(19) United States
(12) Patent Application Publication
(10) Pub. No.: US 2025/0062753 A1
(43) Pub. Date: Feb. 20, 2025

(54) PULSE SIGNAL GENERATING DEVICE AND CONTROL DEVICE THEREOF

(71) Applicant: DigWise Technology Corporation, LTD, Hsinchu County (TW)

(72) Inventors: Hung-Lin Wu, Hsinchu County (TW); Chih-Wen Yang, Hsinchu County (TW); Yu-Chen Lo, Hsinchu County (TW)

(73) Assignee: DigWise Technology Corporation, LTD, Hsinchu County (TW)

(21) Appl. No.: 18/749,575

(22) Filed: Jun. 20, 2024

(30) Foreign Application Priority Data
Aug. 16, 2023 (TW) 112130728

(51) Int. Cl. H03K 3/038

(52) U.S. Cl. CPC H03K 3/038

(57) ABSTRACT

A control device includes multi-stage control circuits. An i-th stage control circuit includes an input signal generator and an acknowledge signal generator. The input signal generator generates an i+1-th stage input signal according to a first inverted output signal and an i+1-th stage acknowledge signal. The acknowledge signal generator generates an i-th stage acknowledge signal according to an i-th stage delayed input signal and a second inverted output signal, wherein i is an integer larger than 1. Phases of the first inverted output signal and the second inverted output signal are opposite to a phase of an i-th stage output signal generated by an i-th stage pulse signal generator.

### CROSS-REFERENCE TO RELATED APPLICATION

This application claims the priority benefit of Taiwan application serial no. 112130728, filed on Aug. 16, 2023. The entirety of the above-mentioned patent application is hereby incorporated by reference herein and made a part of this specification.

### BACKGROUND OF THE INVENTION

### Field of the Invention

The invention relates to a pulse signal generating device and a control device thereof, and in particular to a pulse signal generating device and a control device thereof that may improve the reliability of data transmission between intermediate stages of a circuit and a control device thereof.

### Description of Related Art

In the architecture of dynamic circuits, the control of the dynamic latch has always been the main difficulty of dynamic circuits. In the face of shrinking process dimensions, the reduction in parasitic capacitance values between circuits and the increase in leakage current of transistors as the critical voltage is decreased make it more difficult to effectively achieve dynamic latching of transmitted data. In today's technical field, how to create a stable and accurate pulse signal to control dynamic circuits and optimize the performance and stability of the chip is a difficult challenge in circuit design.

### SUMMARY OF THE INVENTION

The invention provides a pulse signal generating device and a control device thereof that may improve the reliability of data transmission between intermediate and interstage chips.

A control device of the invention is suitable for multi-stage pulse signal generators. The control device includes multi-stage control circuits. The control circuits are respectively coupled to the pulse signal generators, wherein the control circuits are sequentially connected in series with each other, an i-th stage control circuit corresponds to an i-th stage pulse signal generator, and the i-th stage pulse signal generator generates an i-th stage output signal according to an i-th stage input signal. The i-th stage control circuit includes an input signal generator and an acknowledge signal generator. The input signal generator is coupled to the i-th stage pulse signal generator and generates an i+1-th stage input signal according to a first inverted output signal and an i+1-th stage acknowledge signal. The input signal generator provides the i+1-th stage input signal to an i+1-th stage control circuit. The acknowledge signal generator generates an i-th stage acknowledge signal according to an i-th stage delayed input signal and a second inverted output signal, wherein the acknowledge signal generator provides the i-th stage acknowledge signal to an i−1-th stage control circuit. In particular, i is an integer larger than 1, and phases of the first inverted output signal and the second inverted output signal are opposite to a phase of the i-th stage output signal generated by the i-th stage pulse signal generator.

A pulse signal generating device of the invention includes multi-stage pulse signal generators and the above control device. The pulse signal generators are connected in series with each other, wherein an i-th stage pulse signal generator generates an i-th stage output signal according to an i-th stage input signal.

Based on the above, in the control device of the invention, the control circuits at each stage control the input signal sent to the latter stage via the acknowledge signal generated by the acknowledge signal generator of the latter stage. In this way, the pulse width between the output signals generated by the pulse signal generators at each stage may be ensured. Moreover, the spacing between the pulses of adjacent output signals may also be ensured to effectively improve the reliability of data transmission of the circuits of intermediate and interstage chips.

### BRIEF DESCRIPTION OF THE DRAWINGS

FIG. 1 shows a schematic diagram of a pulse signal generating device of an embodiment of the invention.

FIG. 2 shows a schematic diagram of an implementation of a pulse signal generator at each stage of a pulse signal generating device of an embodiment of the invention.

FIG. 3 shows a schematic diagram of a control circuit in a control device of an embodiment of the invention.

FIG. 4A shows a schematic circuit diagram of an input signal generator in a control device of an embodiment of the invention.

FIG. 4B shows a waveform diagram of the operation of the input signal generator of FIG. 4A.

FIG. 5A shows a schematic circuit diagram of an acknowledge signal generator in a control device of an embodiment of the invention.

FIG. 5B shows a waveform diagram of the operation of the acknowledge signal generator of FIG. 5A.

FIG. 5C shows a schematic diagram of another implementation of the acknowledge signal generator of an embodiment of the invention.

FIG. 6A shows a schematic circuit diagram of a pulse signal generator of an embodiment of the invention.

FIG. 6B shows a waveform diagram of the pulse signal generator of FIG. 6A.

FIG. 7 shows a schematic waveform diagram of a pulse signal generating device of an embodiment of the invention.

FIG. 8 shows a schematic waveform diagram of a plurality of output signals generated by a pulse signal generating device of an embodiment of the invention.

### DESCRIPTION OF THE EMBODIMENTS

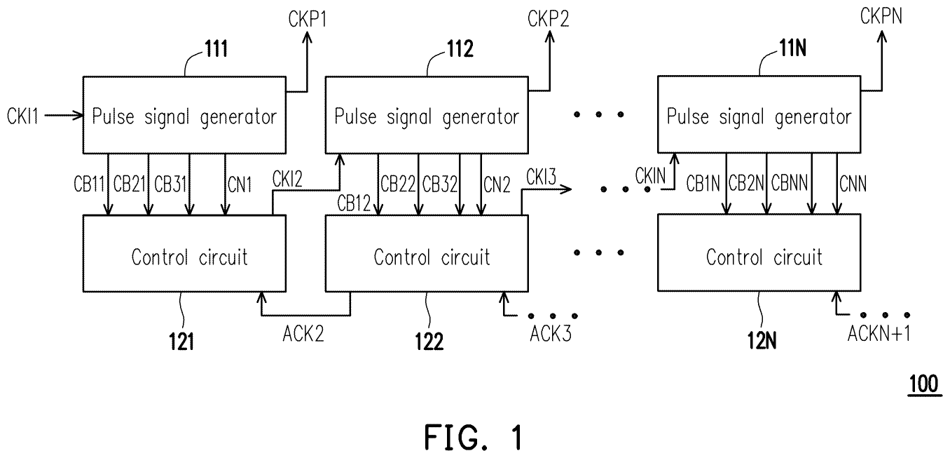

Please refer to FIG. 1. FIG. 1 shows a schematic diagram of a pulse signal generating device of an embodiment of the invention. A pulse signal generating device 100 includes multi-stage pulse signal generators 111 to 11N and a control device formed by multi-stage control circuits 121 to 12N. The pulse signal generators 111 to 11N respectively correspond to the control circuits 121 to 12N. The control circuits 121 to 12N are coupled in series in sequence. In detail, the first-stage control circuit 121 corresponds to the first-stage pulse signal generator 111; the second-stage control circuit 122 corresponds to the second-stage pulse signal generator 112 . . . the N-th stage control circuit 12N corresponds to the N-th stage pulse signal generator 11N. The multi-stage pulse signal generators 111 to 11N generate multi-stage output signals CKP1 to CKPN respectively. The multi-stage output signals CKP1 to CKPN respectively have pulses generated in sequence, which are respectively used as the basis for data latching of the multi-stage circuits.

The control circuits 121 to 12N sequentially generate the multi-stage output signals CKP1 to CKPN. In the present embodiment, the first-stage control circuit 121 may receive an external first-stage input signal CKI1 and generate the output signal CKP1 according to the first-stage input signal CKI1. The second-stage control circuit 122 to the N-stage control circuit 12N respectively receive second-stage to N-stage input signals CKI2 to CKIN respectively generated by the first-stage control circuit 111 to the N−1-stage control circuit (not shown), and respectively generate the second stage to N-th stage output signals CKP2 to CKPN according to the input signals CKI2 to CKIN.

Moreover, the pulse generator 111 generates inverted output signals CB21, CB31, and CN1 according to the inverted output signal of the generated output signal CKP1 and generates a delayed input signal CB11 according to the delayed input signal CKI1; the pulse generator 112 generates inverted output signals CB22, CB32, and CN2 according to the inverted output signal of the generated output signal CKP2 and generates a delayed input signal CB12 according to the delayed input signal CKI2 . . . the pulse generator 11N generates inverted output signals CB2N, CB3N, and CNN according to the inverted output signal of the generated output signal CKPN and generates a delayed input signal CB1N according to the delayed input signal CKIN.

The control circuit 121 receives the inverted output signals CB21, CB31, and CN1, the delayed input signal CB11, and an acknowledge signal ACK2 generated by the subsequent control circuit 122; the control circuit 122 receives the inverted output signals CB22, CB32, and CN2, the delayed input signal CB12, and an acknowledge signal ACK3 generated by the subsequent control circuit . . . the control circuit 12N receives the inverted output signals CBN2, CBN3, and CNN, the delayed input signal CBN1, and an acknowledge signal ACKN+1.

In the present embodiment, taking the second-stage control circuit 122 as an example, the control circuit 122 may generate the input signal CKI3 according to the received inverted output signals CB22 and CN2 and the acknowledge signal ACK3, wherein the input signal CKI3 is sent to the third-stage pulse signal generator and may be called the third-stage input signal. In addition, the control circuit 122 may also generate the (second stage) acknowledge signal ACK2 according to the delayed input signal CB12 and the inverted output signal CB32. The control circuit 122 also provides the acknowledge signal ACK2 to the secondary control circuit.

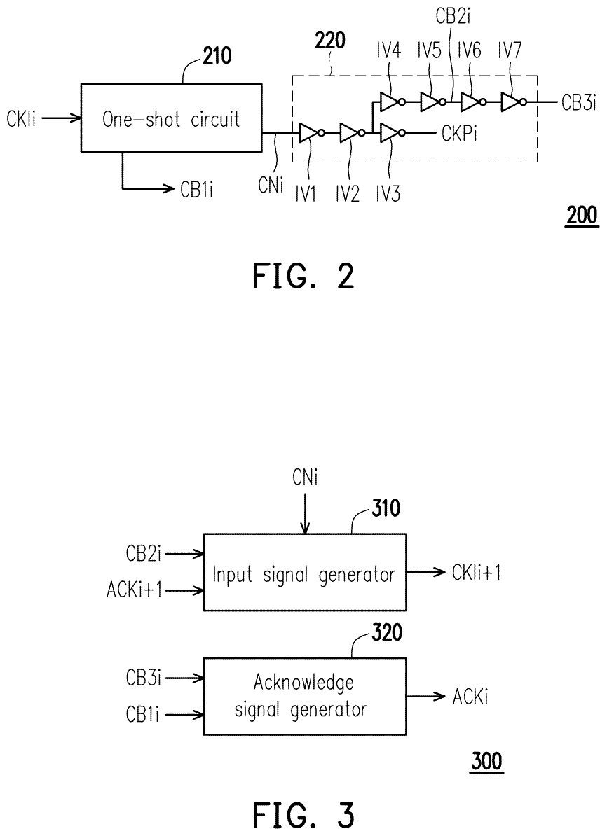

Please refer to FIG. 2 below. FIG. 2 shows a schematic diagram of an implementation of a pulse signal generator at each stage of a pulse signal generating device of an embodiment of the invention. Any one of the pulse signal generators 111 to 11N of the embodiment of FIG. 1 may be implemented using a pulse signal generator 200.

The pulse signal generator 200 is exemplified as an i-th stage pulse signal generator in the pulse signal generating device, wherein i is a positive integer. The pulse signal generator 200 includes a one-shot circuit 210 and an inverter string 220 formed by a plurality of inverters. The one-shot circuit 210 receives an input signal CKIi and generates a pulse signal CNi according to the transition edge of the input signal CKIi. The inverter string 220 is coupled to the output terminal of the one-shot circuit 210 and performs a plurality of inverse operations on the pulse signal CNi to generate inverted output signals CB2i and CB3i and an output signal CKPi respectively. Moreover, the one-shot circuit 210 may delay the input signal CKIi and generate the delayed input signal CB1i.

The inverter string 220 has a plurality of inverters IV1 to IV7. The inverters IV1 to IV3 are coupled to each other in series. The input terminal of the inverter IV1 is coupled to the output terminal of the one-shot circuit 210 and receives the pulse signal CNi. The output terminal of the inverter IV3 generates the output signal CKPi. The inverters IV4 to IV7 are coupled in series with each other, wherein the input terminal of the inverter IV4 is coupled to the output terminal of the inverter IV2. The output terminal of the inverter IV4 generates the inverted output signal CB2i, and the output terminal of the inverter IV7 generates the inverted output signal CB3i.

It is worth mentioning that the one-shot circuit 210 may be implemented by any form of one-shot circuit well known to those having ordinary skill in the art, without specific limitations.

Please refer to FIG. 3 below. FIG. 3 shows a schematic diagram of a control circuit in a control device of an embodiment of the invention. A control circuit 300 includes an input signal generator 310 and an acknowledge signal generator 320. The control circuit 300 is one of the multi-stage control circuits in the control device.

Taking the control circuit 300 as the i-th stage in the multi-stage control circuits as an example, i is a positive integer greater than 1, and the input signal generator 310 receives the inverted output signal CB2i provided by the i-th stage pulse signal generator, the acknowledge signal ACKi+1 provided by the i+1-th stage control circuit 300, and the pulse signal CNi provided by the i-th stage pulse signal generator. The input signal generator 310 generates an i+1-th stage input signal CKIi+1 according to the inverted output signal CB2i, the acknowledge signal ACKi+1, and the pulse signal CNi, wherein the i+1-th stage input signal CKIi+1 is transmitted to the i+1-th stage control circuit. In detail, the input signal generator 310 may set the i+1-th stage input signal CKIi+1 to the first logic value according to the inverted output signal CB2i and set the i+1-th stage input signal CKIi+1 to the second logic value according to the acknowledge signal ACKi+1, and the first logic value and the second logic value are complementary.

Moreover, the acknowledge signal generator 320 receives the i-th stage delayed input signal CB1i and the inverted output signal CB3i and generates the i-th stage acknowledge signal ACKi according to the i-th stage delayed input signal CB1i and the inverted output signal CB3i. In particular, the acknowledge signal generator 320 transmits the i-th stage acknowledge signal ACKi to the i−1-th stage control circuit. In detail, the acknowledge signal generator 320 generates the i-th acknowledge signal ACKi of the second logic value when the i-stage delayed input signal CB1i and the inverted output signal CB3i are both of the second logic value; conversely, when at least one of the i-th stage delayed input signal CB1i and the inverted output signal CB3i is the first logic value, the acknowledge signal generator 320 generates the i-th stage acknowledge signal ACKi of the first logic value.

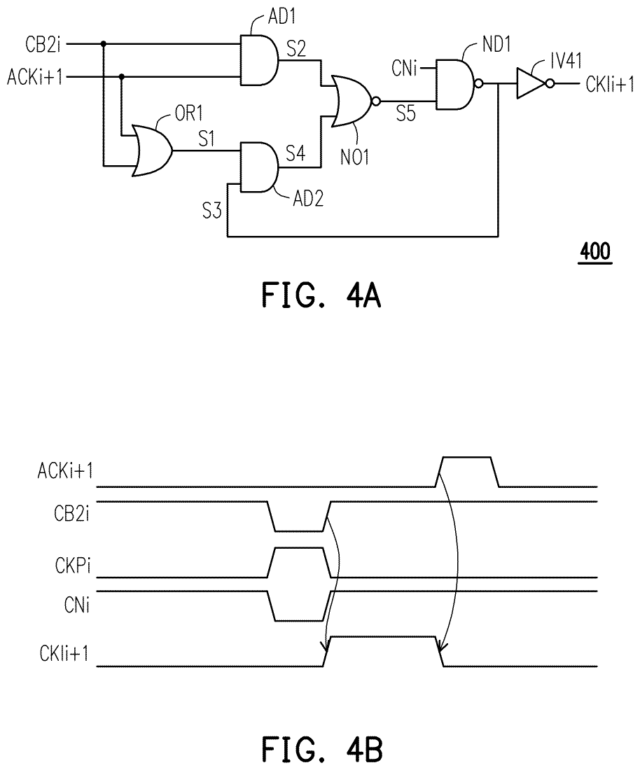

Please refer to FIG. 4A and FIG. 4B below. FIG. 4A is a schematic circuit diagram of an input signal generator in a control device of an embodiment of the invention, and FIG. 4B is an action waveform diagram of the input signal generator of FIG. 4A. An input signal generator 400 includes an OR gate OR1, AND gates AD1 and AD2, a NOR gate NO1, a NAND gate ND1, and an inverter IV41. The OR gate OR1 receives the inverted output signal CB2i and the i+1-th acknowledge signal ACKi+1, and performs an OR logic operation on the inverted output signal CB2i and the i+1-th acknowledge signal ACKi+1 to generate a first signal S1. The AND gate AD1 receives the inverted output signal CB2i and the i+1-th acknowledge signal ACKi+1, and performs an AND logic operation on the inverted output signal CB2i and the i+1-th acknowledge signal ACKi+1 to generate a second signal S2. The AND gate AD2 receives the first signal S1 and a third signal S3 generated by the NAND gate ND1, and performs an AND logic operation on the first signal S1 and the third signal S3 to generate a fourth signal S4. The NOR gate NO1 receives the second signal S2 and the fourth signal S4, and performs a NOR logic operation on the second signal S2 and the fourth signal S4 to generate a fifth signal S5. The NAND gate ND1 receives the fifth signal S5 and the pulse signal CNi and performs a NAND logic operation on the fifth signal S5 and the pulse signal CNi to generate the third signal S3. In particular, the pulse signal CNi may be the inversed signal of the i-th stage output signal CKPi generated by the corresponding i-th stage pulse signal generator. The inverter IV41 receives the third signal S3 and inverts the third signal S3 to generate the i+1-th stage input signal CKIi+1.

In FIG. 4B, the initial states of the i+1-th stage acknowledge signal ACKi+1, the inverted output signal CB2i, the i-th stage output signal CKPi, and the pulse signal CNi are logic values 0, 1, 0, 1 respectively, and the input signal generator 400 correspondingly generates the i+1-th stage input signal CKIi+1 of logic value 0. Next, when the i-th stage output signal CKPi has a positive pulse, the inverted output signal CB2i and the pulse signal CNi correspondingly generate negative pulses. At this time, the OR gate ORI generates the first signal S1 that is also logic value 0 according to the inverted output signal CB2i and the i+1-th stage acknowledge signal ACKi+1 that are both logic value 0. Based on the second signal S2 also being logic value 0, the NOR gate NO1 may generate the fifth signal S5 of logic value 1, and the i+1-th stage input signal CKIi+1 may be set to logic value 1.

Next, when the i+1-th stage acknowledge signal ACKi+1 is transitioned to logic value 1, based on the fact that the inverted output signal CB2i at this time is also logic value 1, the AND gate AD1 may generate the second signal S2 that is logic value 1, and make the fifth signal S5 transition to logic value 0. In this way, the i+1-th stage input signal CKIi+1 may change to logic value 0.

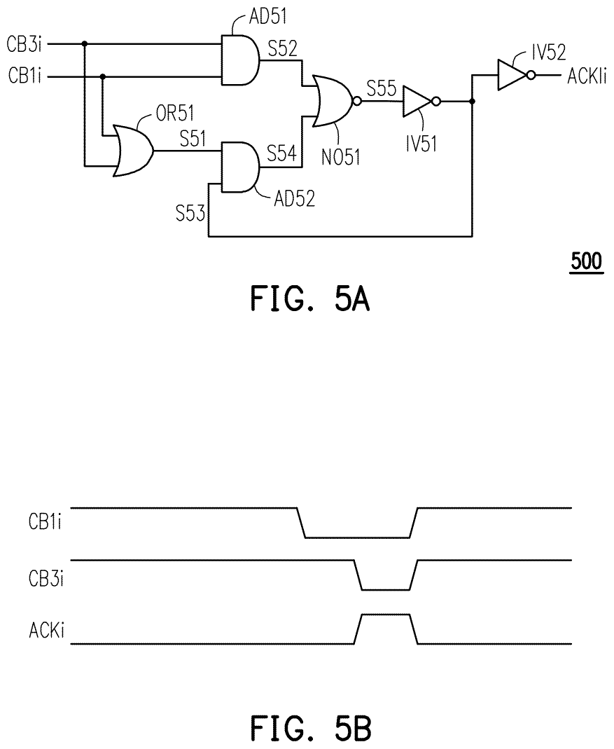

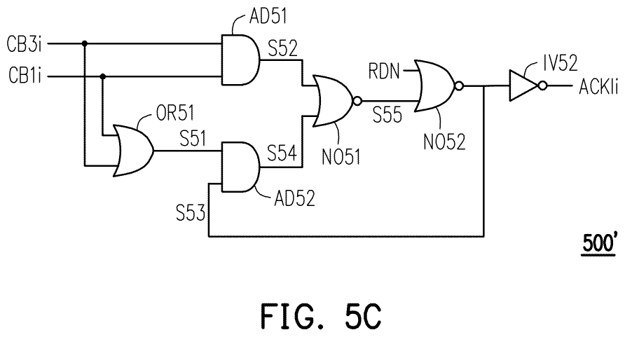

Please refer to FIG. 5A and FIG. 5B below. FIG. 5A is a schematic circuit diagram of an acknowledge signal generator in a control device of an embodiment of the invention, and FIG. 5B is an action waveform diagram of the acknowledge signal generator of FIG. 5A. An acknowledge signal generator 500 includes an OR gate OR51, AND gates AD51 and AD52, a NOR gate NO51, and inverters IV51 and IV52. The OR gate OR51 receives the i-th stage delayed input signal CB1i and the inverted output signal CB3i. The OR gate OR51 performs an OR logic operation on the i-th stage delayed input signal CB1i and the inverted output signal CB3i to generate a first signal S51. The AND gate AD51 receives the i-th stage delayed input signal CB1i and the inverted output signal CB3i and performs an AND logic operation on the i-th stage delayed input signal CB1i and the inverted output signal CB3i to generate a second signal S52. The AND gate AD2 receives the first signal S51 and a third signal S53 generated by the inverter IV51, and performs an AND logic operation on the first signal S51 and the third signal S53 to generate a fourth signal S54. The NOR gate NO1 receives the second signal S52 and the fourth signal S54, and performs a NOR logic operation on the second signal S52 and the fourth signal S54 to generate a fifth signal S55. The inverter IV51 generates the third signal S53 by inverting the fifth signal S55, and the inverter IV52 generates the i-th stage acknowledge signal ACKi by inverting the third signal S53.

In FIG. 5B, the i-th stage delayed input signal CB1i may be the delay and inversion of the i-th stage input signal received by the i-th stage pulse signal generator. The inverted output signal CB3i may be the inverted signal of the i-th stage output signal generated by the i-th stage pulse signal generator. Therefore, the negative pulse of the inverted output signal CB3i may occur after the negative pulse of the i-th stage delayed input signal CB1i. When the inverted output signal CB3i and the i-th stage delayed input signal CB1i are both logic value 0, the acknowledge signal generator 500 may generate the i-th stage acknowledge signal ACKi of logic value 1. Moreover, when at least one of the inverted output signal CB3i and the i-th stage delayed input signal CB1i returns to logic value 1, the acknowledge signal generator 500 may generate the i-th stage acknowledge signal ACKi of logic value 0.

According to the waveform in FIG. 4B, it may be clearly seen that the pulse width of the i+1-th stage input signal CKIi+1 may be determined according to the time difference between the end time point of the negative pulse of the inverted output signal CB2i and the occurrence time point of the positive pulse of the i+1-th stage acknowledge signal ACKi+1. Moreover, it may be clearly understood from the waveform of FIG. 5B that the i+1-th stage acknowledge signal ACKi+1 may be related to the i+1-th stage output signal generated by the i+1-th stage pulse signal generator. That is, the input signals received by the pulse signal generators at various stages in an embodiment of the invention may have a sufficiently long pulse width, and the pulse waves of the output signals respectively generated by the pulse signal generators do not interfere with each other, ensuring the accuracy of data transmission in circuits at all stages.

Please refer to FIG. 5C below. FIG. 5C shows a schematic diagram of another implementation of an acknowledge signal generator of an embodiment of the invention. Comparing with the implementation of FIG. 5A, in an acknowledge signal generator 500′, the inverter IV51 in FIG. 5A is replaced by a NOR gate NO52. In addition to receiving the fifth signal S55, the NOR gate NO52 also receives a reset signal RDN. In particular, when the reset signal RDN is logic value 1, the i-th stage acknowledge signal ACKi may be reset to logic value 1.

It is worth noting that among the plurality of logic circuits shown in FIG. 4A, FIG. 5A, and FIG. 5C, the logic gates and combinations thereof may all be replaced by one or a plurality of logic gates that may achieve the same function, and are not necessarily limited to the circuit configurations of FIG. 4A, FIG. 5A, and FIG. 5C. The replacement actions of the logic gate should be familiar to digital circuit designers having ordinary skill, and are not described in detail here.

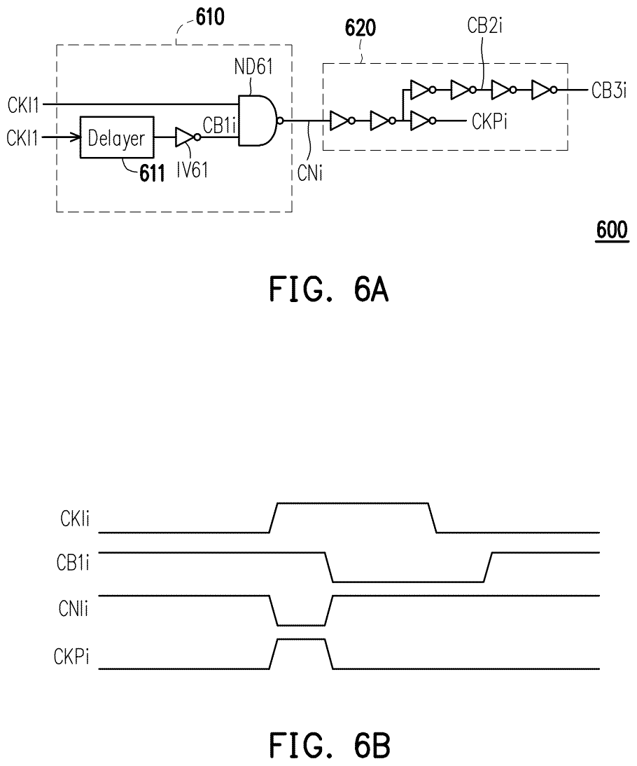

Please refer to FIG. 6A and FIG. 6B below. FIG. 6A shows a circuit schematic diagram of a pulse signal generator of an embodiment of the invention, and FIG. 6B shows a waveform diagram of the pulse signal generator of FIG. 6A. Taking a pulse signal generator 600 as an i-th stage pulse signal generator as an example, the pulse signal generator 600 includes a one-shot circuit 610 and an inverter string 620. The one-shot circuit 610 includes a delayer 611, an inverter IV61, and a NAND gate ND61. An input terminal of the NAND gate ND61 directly receives the i-th stage input signal CKIi, and another input terminal of the NAND gate ND61 receives the i-th stage input signal CKIi via the delayer 611 and the inverter IV61 connected in series with each other. The delayer 611 provides a delay phase, and performs phase delay on the i-th stage input signal CKIi. The inverter IV61 inverts the output of the delayer 611 and generates a delayed input signal CKIi. The negative AND gate ND61 generates a negative pulse of the pulse signal CNIi according to the phase difference between the i-th stage input signal CKIi and the delayed input signal CKIi, as shown in FIG. 6B.

In addition, the inverter string 620 has a plurality of serially connected inverters. The inverter string 620 performs a plurality of inversion operations on the pulse signal CNIi to generate the i-th stage output signal CKPi and the inverted output signals CB2i and CB3i. In particular, the phase of the i-th stage output signal CKPi is opposite to the phase to the pulse signal CNIi (as shown in FIG. 6B).

The delayer 611 may be constructed by a delay circuit well known to those having ordinary skill in the art, without any specific limitation.

It is worth mentioning that the circuit details of the pulse signal generator 600 in the present embodiment are only an exemplary implementation. Any circuit architecture of a pulse signal generator well known to those having ordinary skill in the art may be applied to the invention without certain limitations.

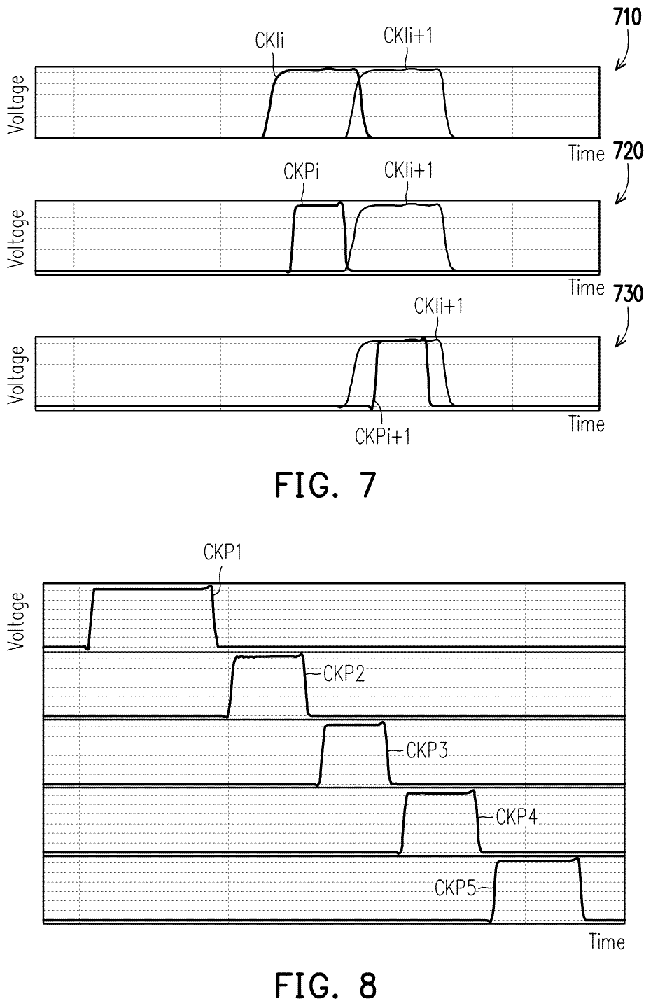

Please refer to FIG. 7 below. FIG. 7 shows a schematic waveform diagram of a pulse signal generating device of an embodiment of the invention. In the waveform of FIG. 7, the horizontal axis represents time and the vertical axis represents voltage.

In field 710, the pulse signal generating device may continuously generate the i-th stage input signal CKIi and the i+1-th stage input signal CKIi+1. According to the input signal CKIi, the i-th stage pulse signal generator in the pulse signal generating device may generate the output signal CKPi according to the input signal CKIi, as shown in field 720. In addition, in field 730, the i+1-th stage pulse signal generator in the pulse signal generating device may generate the output signal CKPi+1 according to the input signal CKIi+1. In particular, the pulse of the i+1-th stage input signal CKIi+1 may completely cover the i+1-th stage output signal CKPi+1 generated by the i+1-th stage pulse signal generator on the time axis.

Please refer to FIG. 8 below. FIG. 8 shows a schematic waveform diagram of a plurality of output signals generated by a pulse signal generating device of an embodiment of the invention. Taking the pulse signal generating device as having a 5th stage pulse signal generator as an example, the 5th stage pulse signal generator may generate the output signals CKP1 to CKP5 from the 1st stage to the 5th stage respectively. In particular, the positive pulses of the output signals CKP1 to CKP5 are not overlapped with each other, and the widths of the positive pulses of any two of the output signals CKP1 to CKP5 may be the same or different. That is, the pulse width of the output signal generated by the pulse signal generating device of an embodiment of the invention may be dynamically adjusted, instead of having a fixed same pulse width. The pulse signal generating device may further ensure the reliability of data transmission by dynamically adjusting the pulse width of the generated output signal.

Based on the above, the pulse signal generating device of the invention is provided with multi-stage control circuits, and the secondary input signal is generated via the control circuit at each stage and the pulse width of the secondary input signal is dynamically adjusted according to the acknowledge signal generated by the secondary control circuit. In this way, via the handshake agreement between various stages, the pulse width of the output signal at each stage and the time point of triggering the pulse may be dynamically adjusted to ensure the stability of data transmission in circuits at all stages and improve system performance.

What is claimed is:

1. A control device, suitable for multi-stage pulse signal generators, comprising:
multi-stage control circuits respectively coupled to the pulse signal generators, wherein the control circuits are sequentially connected in series with each other, an i-th stage control circuit corresponds to an i-th stage pulse signal generator, and the i-th stage pulse signal generator generates an i-th stage output signal according to an i-th stage input signal,
the i-th stage control circuit comprises:
an input signal generator coupled to the i-th stage pulse signal generator and generating an i+1-th stage input signal according to a first inverted output signal and an i+1-th stage acknowledge signal, wherein the input signal generator provides the i+1-th stage input signal to an i+1-th stage control circuit; and
an acknowledge signal generator generating an i-th stage acknowledge signal according to an i-th stage delayed input signal and a second inverted output signal, wherein the acknowledge signal generator provides the i-th stage acknowledge signal to an i−1-th stage control circuit,
wherein i is an integer larger than 1, and phases of the first inverted output signal and the second inverted output signal are opposite to a phase of the i-th stage output signal of the i-th stage pulse signal generator.

2. The control device of claim 1, wherein there is a delay phase between the i-th stage delayed input signal and the i-th stage input signal.

3. The control device of claim 1, wherein the input signal generator sets the i+1-th stage input signal to a first logic value according to the first inverted output signal, the input signal generator sets the i+1-th stage input signal to a second logic value according to the i+1-th stage acknowledge signal, and the first logic value is complementary to the second logic value.

4. The control device of claim 3, wherein the acknowledge signal generator generates the i-th stage acknowledge signal of the second logic value when the i-th stage delayed input signal and the second inverted output signal are both of the second logic value.

5. The control device of claim 1, wherein a pulse of the i+1-th stage input signal completely covers an i+1-th stage output signal generated by an i+1-th stage pulse signal generator on a time axis.

6. The control device of claim 1, wherein the input signal generator comprises:
an OR gate receiving the first inverted output signal and the i+1-th stage acknowledge signal and generating a first signal;
a first AND gate receiving the first inverted output signal and the i+1-th stage acknowledge signal and generating a second signal;
a second AND gate receiving the first signal and a third signal and generating a fourth signal;
a NOR gate receiving the second signal and the fourth signal and generating a fifth signal;
a NAND gate generating a sixth signal according to the fifth signal and the i-th stage output signal; and
an inverter generating the i+1-th stage input signal according to the sixth signal.

7. The control device of claim 1, wherein the acknowledge signal generator comprises:
an OR gate receiving the i-th stage delayed input signal and the second inverted output signal and generating a first signal;
a first AND gate receiving the i-th stage delayed input signal and the second inverted output signal and generating a second signal;
a second AND gate receiving the first signal and a third signal and generating a fourth signal;
a NOR gate receiving the second signal and the fourth signal and generating a fifth signal;
a first inverter inverting the fifth signal to generate the third signal; and
a second inverter inverting the third signal to generate the i-th stage acknowledge signal.

8. The control device of claim 1, wherein the acknowledge signal generator comprises:
an OR gate receiving the i-th stage delayed input signal and the second inverted output signal and generating a first signal;
a first AND gate receiving the i-th stage delayed input signal and the second inverted output signal and generating a second signal;
a second AND gate receiving the first signal and a third signal and generating a fourth signal;
a first NOR gate receiving the second signal and the fourth signal and generating a fifth signal;
a second NOR gate receiving the fifth signal and a reset signal and generating the third signal; and
a first inverter inverting the third signal to generate the i-th stage acknowledge signal.

9. A pulse signal generating device, comprising:
multi-stage pulse signal generators, wherein an i-th stage pulse signal generator generates an i-th stage output signal according to an i-th stage input signal; and
a control device comprising multi-stage control circuits, wherein the control circuits are connected in series with each other and respectively coupled to the pulse signal generators, an i-th stage control circuit corresponds to the i-th stage pulse signal generator, and the i-th stage control circuit comprises:
an input signal generator coupled to the i-th stage pulse signal generator and generating an i+1-th stage input signal according to a first inverted output signal and an i+1-th stage acknowledge signal, wherein the input signal generator provides the i+1-th stage input signal to an i+1-th stage control circuit; and
an acknowledge signal generator generating an i-th stage acknowledge signal according to an i-th stage delayed input signal and a second inverted output signal, wherein the acknowledge signal generator provides the i-th stage acknowledge signal to an i−1-th stage control circuit,
wherein i is an integer larger than 1, and phases of the first inverted output signal and the second inverted output signal are opposite to a phase of the i-th stage output signal of the i-th stage pulse signal generator.

10. The pulse signal generating device of claim 8, wherein the i-th stage pulse signal generator comprises:
a one-shot circuit generating a pulse signal according to a transition edge of the i-th stage input signal; and
a plurality of inverters, wherein the inverters are connected in series with each other and coupled to an output terminal of the one-shot circuit, and the inverters invert the pulse signal a plurality of times to respectively generate the i-th stage output signal, the first inverted output signal, and the second inverted output signal.

11. The pulse signal generating device of claim 9, wherein the one-shot circuit comprises:
a delayer delaying the i-th stage input signal to generate the i-th stage delayed input signal;
an inverter coupled to an output terminal of the delayer to receive the i-th stage delayed input signal; and
a logic gate performing a logic operation on the i-th stage input signal and an output signal of the inverter to generate a pulse signal.

12. The pulse signal generating device of claim 8, wherein the input signal generator sets the i+1-th stage input signal to a first logic value according to the first inverted output signal, the acknowledge signal generator sets the i+1-th stage input signal to a second logic value according to the i+1-th stage acknowledge signal, and the first logic value is complementary to the second logic value.

13. The pulse signal generating device of claim 11, wherein the acknowledge signal generator generates the i-th stage acknowledge signal of the second logic value when the i-th stage delayed input signal and the second inverted output signal are both of the second logic value.

14. The pulse signal generating device of claim 8, wherein a pulse of the i+1-th stage input signal completely covers an i+1-th stage output signal generated by an i+1-th stage pulse signal generator on a time axis.

15. The pulse signal generating device of claim 8, wherein the input signal generator comprises:
an OR gate receiving the first inverted output signal and the i+1-th stage acknowledge signal and generating a first signal;
a first AND gate receiving the first inverted output signal and the i+1-th stage acknowledge signal and generating a second signal;
a second AND gate receiving the first signal and a third signal and generating a fourth signal;
a NOR gate receiving the second signal and the fourth signal and generating a fifth signal;
a NAND gate generating the third signal according to the fifth signal and the i-th stage output signal; and
an inverter generating the i+1-th stage input signal according to the third signal.

16. The pulse signal generating device of claim 8, wherein the acknowledge signal generator comprises:
an OR gate receiving the i-th stage delayed input signal and the second inverted output signal and generating a first signal;
a first AND gate receiving the i-th stage delayed input signal and the second inverted output signal and generating a second signal;
a second AND gate receiving the first signal and a third signal and generating a fourth signal;
a NOR gate receiving the second signal and the fourth signal and generating a fifth signal;
a first inverter inverting the fifth signal to generate the third signal; and
a second inverter inverting the third signal to generate the i-th stage acknowledge signal.

17. The pulse signal generating device of claim 8, wherein the acknowledge signal generator comprises:
an OR gate receiving the i-th stage delayed input signal and the second inverted output signal and generating a first signal;
a first AND gate receiving the i-th stage delayed input signal and the second inverted output signal and generating a second signal;
a second AND gate receiving the first signal and a third signal and generating a fourth signal;
a first NOR gate receiving the second signal and the fourth signal and generating a fifth signal;
a second NOR gate receiving the fifth signal and a reset signal and generating the third signal; and
a first inverter inverting the third signal to generate the i-th stage acknowledge signal.
